(19) United States
(12) Patent Application Publication
(10) Pub. No.: US 2010/0052765 A1
(43) Pub. Date: Mar. 4, 2010

(54) SEMICONDUCTOR INTEGRATED CIRCUIT AND METHOD OF LEVELING SWITCHING NOISE THEREOF

(75) Inventor: Yasuyuki Makino, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/552,947

(22) Filed: Sep. 2, 2009

(30) Foreign Application Priority Data
Sep. 3, 2008 (JP) 2008-226036

(51) Int. Cl. H03K 17/16

(52) U.S. Cl. 327/384

(57) ABSTRACT

A semiconductor integrated circuit includes a switching circuit, a switch, and a switch control circuit. The switch changes over whether a decoupling capacitor is connected to a power source of the switching circuit. The switch control circuit detects a control signal that causes switching of the switching circuit, and turns on the switch for a fixed period of time that straddles switching of the switching circuit, thereby connects the decoupling capacitor to the power source of the switching circuit. The decoupling capacitor is connected to the power source only when the switching circuit switches. As a result, a difference in noise between noise when switching is performed and noise when switching is not performed can be reduced.

### REFERENCE TO RELATED APPLICATION

This application is based upon and claims the benefit of the priority of Japanese patent application No. 2008-226036, filed on Sep. 3, 2008, the disclosure of which is incorporated herein in its entirety by reference thereto.

### TECHNICAL FIELD

This invention relates to a semiconductor integrated circuit. More particularly, the invention relates to an semiconductor integrated circuit having a circuit such as an output buffer that inflicts switching noise upon a power source.

### BACKGROUND

Owing to greater process microfabrication, lower supply voltage, mixing of analog and digital circuits, high-speed interfaces and an increase in packing density of packages and mounting substrates in recent years, a power integrity (PI) problem, which is ascribable to simultaneous switching noise due to an output buffer, substrate noise or power source noise such as EMI, and a signal integrity (SI) problem, which is ascribable to the signal waveform such as reflection or crosstalk, have become more acute. In particular, when a high-speed interface such as a DDR or PCI is mounted on a semiconductor substrate, a signal quality degradation which is a jitter increase especially is caused by PI and SI, it is a serious problem. By that problem, we suffer from timing design on the picosecond order. The main cause of an increase in jitter in a high-speed interface is simultaneous switching noise of an output buffer due to an increase in signal speed and a greater number of bits. A reduction in such noise is desired.

FIG. 8 is a block diagram illustrating a conventional semiconductor device, described in Patent Document 1, in which noise in a power source line or ground line has been reduced.

In this example of the prior art, a circuit block (A) 101 and a circuit block (B) 102 exist on a semiconductor device 103 on the same substrate, and a power source line 109 and ground line 110 are connected by wiring to a voltage source 104 via terminals 105 to 108. Parasitic elements R101 to R112 are produced by the wiring length and method of routing. The device is further provided with a non-volatile memory 111. A plurality of capacitors (bypass capacitors) C101 to C104 and a plurality of switch elements S101 to S104, which are connected to the non-volatile memory 111, are connected between the power source line 109 and the ground line 110.

In the conventional semiconductor device illustrated in FIG. 8, the plurality of switch elements S101 to S104 connected to the non-volatile memory 111 are operated to change the state of the connection of the plurality of capacitors C101 to C104 provided between the power source line 109 and ground line 110, whereby information concerning the optimum connection state for which the noise and leakage signal are minimum is obtained. This information is stored in the non-volatile memory 111.

Thus, according to the description rendered in Patent Document 1, the state of connection of the plurality of capacitors C101 to C104 serving as bypass capacitors is changed over appropriately based upon the information that has been stored in the non-volatile memory 111, whereby the capacitance value of the bypass capacitors is changed. As a result, the capacitance value can be set to an optimum capacitance value conforming to a change in circuit operating frequency or surrounding environment, etc.

Further, according to the description rendered in Patent Document 2, a noise measurement circuit is provided and the capacitance value of a decoupling capacitor is controlled after the fact based upon the measured amount of noise.

### [Patent Document 1]

JP Patent Kokai Publication No. JP-P2006-295027A

### [Patent Document 2]

JP Patent Kokai Publication No. JP-P2008-085321A

### SUMMARY

The entire disclosures of Patent Documents 1 and 2 are incorporated herein by reference thereto.

In accordance with investigations by the inventors, it has been found that power source noise is produced in a semiconductor integrated circuit owing to the existence of a number of switching circuits and the switching operation thereof. Further, in a case where a plurality of the switching circuits having a large switching current change from the high to the low level or from the low to the high level simultaneously, there are times when high power source noise is produced and times when such noise is not produced, depending upon the conditions and timing of the switching operation of these switching circuits. The absolute magnitude of power source noise can be suppressed by connecting a decoupling capacitor to the power source. However, the fact that there are times and conditions where a high power source noise is produced and times and conditions where such noise is not produced remains unchanged. The same is true even if the capacitance value of the decoupling capacitor is changed over statically, as in Patent Document 1 or 2.

In such cases, if circuit operation overlaps the timing and conditions at which a high power source noise is produced, a worst-case singularity may exist at which jitter worsens. Often, moreover, this worst case has no reproducibility. Accordingly, an increase in power source noise owing to specific timings and conditions is undesirable from the standpoint of reliability of circuit operation. Preferably, even if power source noise exists, high switching noise should be suppressed and variations in switching noise between times when switching noise is high and times when it is low should be leveled.

According to a first aspect of the present invention, there is provided a semiconductor integrated circuit including a switching circuit, a switch, and a switch control circuit. The switch changes over whether a decoupling capacitor is connected to a power source of the switching circuit. The switch control circuit detects a control signal that causes switching of the switching circuit, and turns on the switch for a fixed period of time that straddles switching of the switching circuit, thereby connecting the decoupling capacitor to the power source of the switching circuit.

Further, According to a second aspect of the present invention, there is provided a semiconductor integrated circuit including a plurality of switching circuits, a plurality of switches, and a plurality of switch control circuits. The plurality of switches are provided in correspondence with respective ones of the plurality of switching circuits for changing over whether decoupling capacitors are connected to a power source of the corresponding switching circuits. The plurality of switch control circuits are provided in correspondence with respective ones of the plurality of switching circuits for detecting control signals that cause switching of the corresponding switching circuits, and turn on the corresponding switches for a fixed period of time that straddles switching of the corresponding switching circuits.

According to a third aspect of the present invention, there is provided A method of leveling switching noise in a semiconductor integrated circuit having a plurality of switching circuits. The method includes: providing the semiconductor integrated circuit with switches, which change over whether decoupling capacitors are connected to a power source of the switching circuits, and switch control circuits, which control on/off operation of the switches, in correspondence with those of the plurality of switching circuits exhibiting a high switching noise; turning on the switches for a fixed period of time that straddles switching of the switching circuits to thereby connect the decoupling capacitors to the power source and suppress switching noise due to the switching circuits.

The meritorious effects of the present invention are summarized as follows.

In accordance with the present invention, a decoupling capacitor is connected to the power source of a switching circuit for a fixed period of time that straddles switching of the switching circuit, switching noise in the switching circuit can be suppressed and variations between times when switching noise is high and times when it is low can be leveled.

Other features and advantages of the invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a block diagram of a semiconductor integrated circuit according to a first example of the present invention;

FIG. 2 is a timing chart of the semiconductor integrated circuit according to the first example of the present invention;

FIGS. 3A-3C are diagrams useful in describing the principle of operation of the present invention;

FIG. 4 is a block diagram of a semiconductor integrated circuit according to a second example of the present invention;

FIG. 5 is a block diagram of a semiconductor integrated circuit according to a third example of the present invention;

FIG. 6 is a block diagram of a semiconductor integrated circuit according to a fourth example of the present invention;

FIG. 7 is a block diagram of a semiconductor integrated circuit according to a fifth example of the present invention; and

FIG. 8 is a block diagram of a conventional semiconductor device described in Patent Document 1.

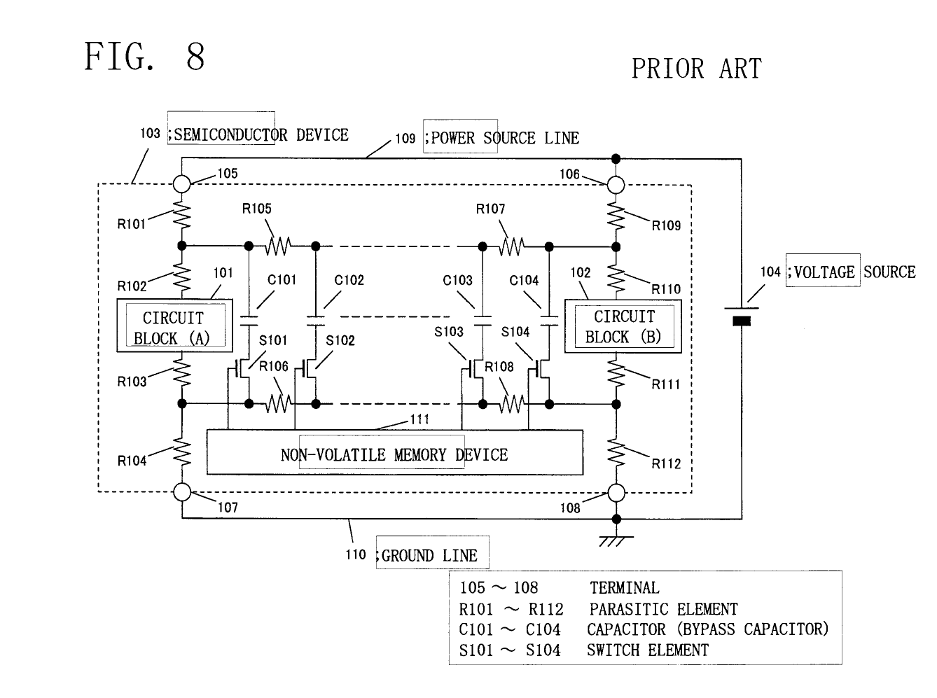

### PREFERRED MODES

The present invention will be described with reference to the drawings as required.

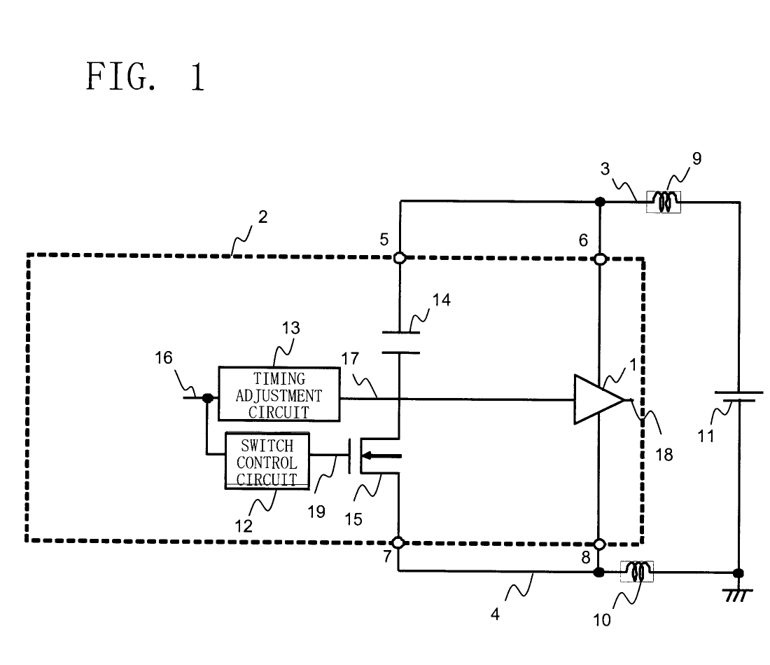

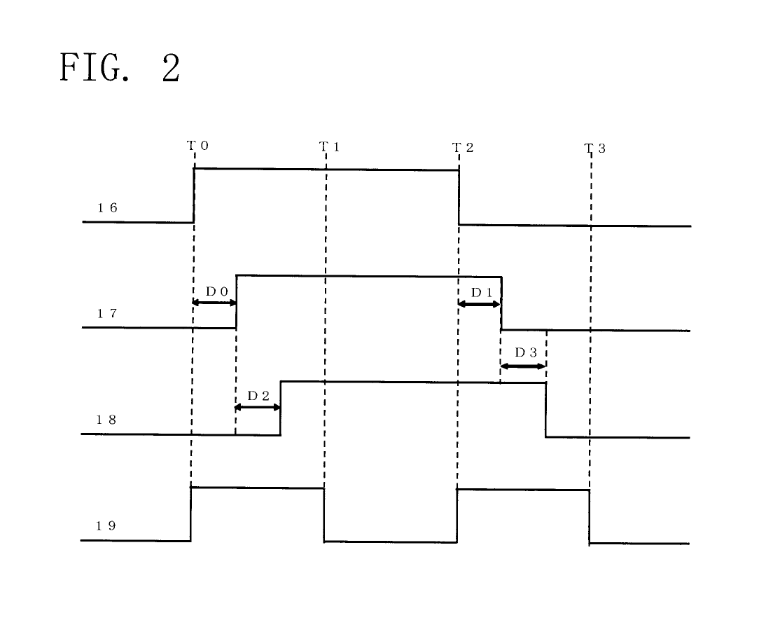

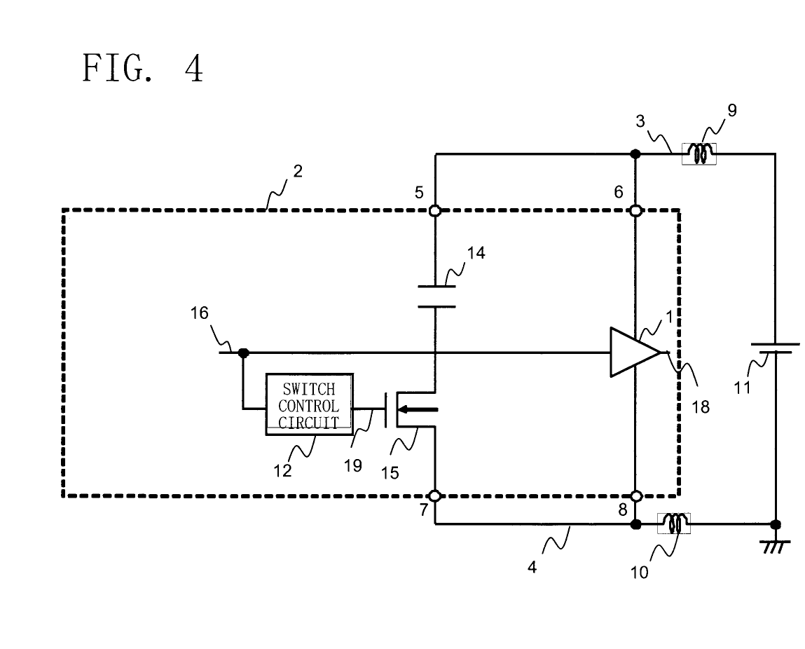

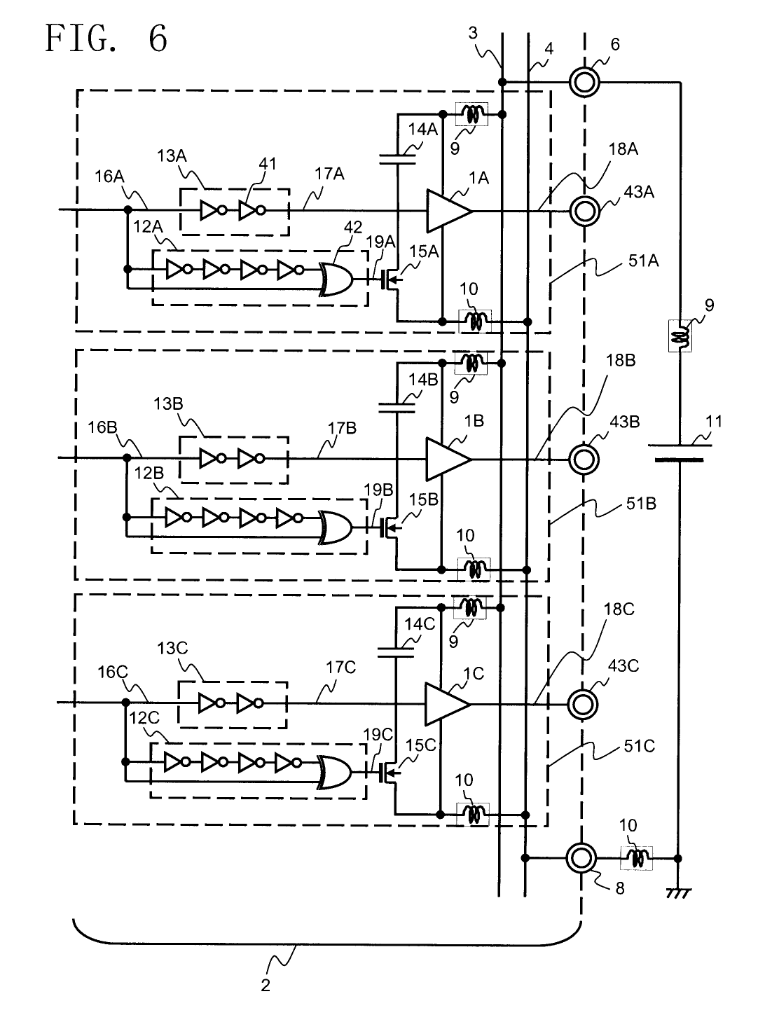

By way of example, as illustrated in FIG. 1 and in FIGS. 4 to 7, a semiconductor integrated circuit in an exemplary embodiment of the present invention includes: a switching circuit (1, 24); a switch 15 for changing over whether a decoupling capacitor (14, 34) is connected to a power source (11, 33) of the switching circuit (1, 24); and a switch control circuit 12 for detecting a control signal 16, which causes switching of the switching circuit (1, 24), and turning on the switch 15 for a fixed period of time (T0 to T1, T2 to T3 in FIG. 2) that straddles switching of the switching circuit (1, 24), thereby connecting the decoupling capacitor (14, 34) to the power source (11, 33) of the switching circuit (1, 24). It should be noted that in a case where reference characters in FIG. 6 have A, B or C added onto the above-mentioned reference characters, the elements should be read with the A, B or C added onto the reference characters. For example, “switching circuit 1” should be read “switching circuits 1A, 1B, 1C. The same is true for the other elements.

In accordance with the semiconductor integrated circuit described above, the decoupling capacitor can be connected to the power source of the switching circuit over a fixed period of time that straddles switching of the switching circuit. As a result, switching noise produced by switching of the switching circuit can be suppressed and the magnitude of power source noise can be leveled.

Further, the semiconductor integrated circuit of this exemplary embodiment may incorporate the decoupling capacitor 14, as shown in FIGS. 1, 4, 6 and 7.

Further, as shown in FIG. 1 and in FIGS. 4 to 7, in the semiconductor integrated circuit of this exemplary embodiment, the switching circuit (1, 24) may be a buffer circuit (1, 24), and the switch control circuit 12 may detect the edge of the input signal 16 to the buffer circuit (1, 24) and turn on the switch 15.

Further, as shown in FIGS. 1, 6 and 7, the semiconductor integrated circuit of this exemplary embodiment may further include a timing adjustment circuit 13 for receiving the control signal 16 and adjusting the timing of switching of the switching circuit (1, 24) and the timing at which the switch is turned on.

The switch 15 need only be turned on for the fixed time period (T0 to T1, T2 to T3 in FIG. 2) that straddles the switching of the switching circuit (1, 24). It will therefore suffice to provide the timing adjustment circuit 13 in a case where it is necessary to delay the switching timing of the switching circuit (1, 24) until the switch 15 turns on. The timing adjustment circuit 13 need not be provided in a case where, upon receiving the control signal 16, the switch control circuit 12 can turn on the switch 15 earlier than the switching of the switching circuit (1, 24).

Further, as illustrated in FIG. 6, a semiconductor integrated circuit in an exemplary embodiment of the present invention may include: a plurality of switching circuits (1A to 1C); a plurality of switches (15A to 15C) provided in correspondence with respective ones of the plurality of switching circuits (1A to 1C) for changing over whether decoupling capacitors (14A to 14C) are connected to a power source (11) of the corresponding switching circuits (1A to 1C); and a plurality of switch control circuits (12A to 12C) provided in correspondence with respective ones of the plurality of switching circuits (1A to 1C) for detecting control signals (16A to 16C), which cause switching of the corresponding switching circuits (1A to 1C), and turning on the corresponding switches (15A to 15C) for a fixed period of time (T0 to T1, T2 to T3 in FIG. 2) that straddles switching of the corresponding switching circuits (1A to 1C).

In a semiconductor integrated circuit having multiple functions, it is difficult to achieve overall management inclusive of management of the timings at which the switching circuits having the individual functions switch. In accordance with the arrangement described above, the decoupling capacitors can be connected to the power source for the fixed period of time, which straddles the switching of the switching circuits, independently for each of the plurality of switching circuits. Accordingly, there is no need to take into consideration the operation timings of switching circuits other than the operation timing of a particular individual switching circuit. In other words, it is unnecessary to consider whether another switching circuit having a function separate from that the applicable switching circuit performs switching simultaneously. Further, in the case of a CMOS-configured semiconductor integrated circuit, all of the logic circuits are switching circuits. However, it is not necessary to provide all of the switching circuits with decoupling capacitors. Leveling of power source noise can be achieved by connecting a decoupling capacitor to the power source of the switching circuits for the fixed period of time that straddles the switching operation, in conformity with the switching operation of output buffer circuits exhibiting a large switching current among the switching circuits or the switching operation of a clock tree in which a number of switching circuits operate simultaneously.

The semiconductor integrated circuit in this exemplary embodiment may incorporate a plurality of decoupling capacitors (14A to 14C) connected to respective ones of the plurality of switches (15A to 15C).

By incorporating the plurality of decoupling capacitors (14A to 14C), the number of parts externally attached to the semiconductor integrated circuit and the number of external capacitor connecting terminals of the semiconductor integrated circuit can be reduced.

Further, as shown in FIG. 6, in the semiconductor integrated circuit of this exemplary embodiment, the plurality of switching circuits (1A to 1C) may be output buffer circuits (1A to 1C) connected to corresponding external output terminals (43A to 43C) of the semiconductor integrated circuit, and the plurality of switch control circuits (12A to 12C) may detect the edges of input signals (16A to 16C) to the output buffer circuits (1A to 1C) and turn on the corresponding switches (15A to 15C).

Further, as shown in FIG. 6, the semiconductor integrated circuit of this exemplary embodiment may further include timing adjustment circuits (13A to 13C), which are provided for respective ones of the plurality of switching circuits (1A to 1C), for receiving the control signals (16A to 16C) and adjusting the timings of switching of the switching circuits (1A to 1C) and the timings at which the switches (15A to 15C) are turned on.

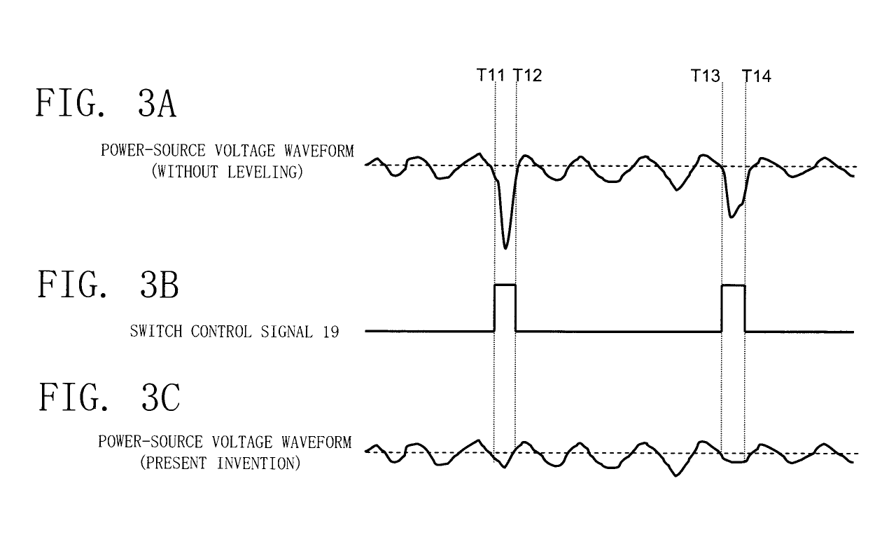

Furthermore, as shown in FIGS. 1, 3A-3C and in FIGS. 4 to 7, a method of leveling (see FIGS. 3A and 3C) switching noise in a semiconductor integrated circuit 2 having a plurality of switching circuits according to an exemplary embodiment of the present invention includes providing the semiconductor integrated circuit 2 with a switch 15, which changes over whether a decoupling capacitor 14 is connected to a power source (11, 33) of the switching circuits, and a switch control circuit 12, which controls on/off operation of the switch, in correspondence with a switching circuit that exhibits a high switching noise among the plurality of switching circuits (1, 24); and turning on the switch 15 for a fixed period of time (T0 to T1, T2 to T3 in FIG. 2) that straddles switching of the switching circuit 1 to thereby connect the decoupling capacitor to the power source (11, 33) and suppress switching noise due to this switching circuit 1 (see FIGS. 3A and 3C).

In accordance with the method described above, since the decoupling capacitor 14 is connected to the power source (11, 33) for a fixed period of time that straddles switching of the switching circuit 1, switching noise due to the switching circuit 1 (see T11 to T12, T13 to T14 in FIG. 3A) can be suppressed (see T11 to T12, T13 to T14 in FIG. 3C) and power source noise can be leveled. That is, the occurrence of high power source noise at timings T11 to T12 or T13 to T14 in FIG. 3A can be suppressed and power source noise can be leveled. Accordingly, even in a case where the timings of occurrence of high power source noise as at timings T11 to T12 or T13 to T14 in FIG. 3A coincides with operation timing of another circuit, jitter in particular will not worsen at such timing. That is, in accordance with the above-described method, degradation of a characteristic such as jitter and malfunction can be prevented when it so happens that circuit operation timing overlaps high power source noise.

Furthermore, as shown in FIG. 6, in the method of leveling switching noise in the semiconductor integrated circuit 2 according to an exemplary embodiment of the present invention, the switching circuits that exhibit a high switching noise are a plurality of output buffer circuits (1A to 1C); a plurality of decoupling capacitors (14A to 14C), a plurality of switches (15A to 15C) and a plurality of switch control circuits (12A to 12C) are internally provided in the semiconductor integrated circuit 2 in correspondence with respective ones of the plurality of output buffer circuits (1A to 1C); and when outputs of the plurality of output buffer circuits (1A to 1C) are inverted, the respective corresponding switches (15A to 15C) are turned on to thereby level the effects of switching noise due to the plurality of output buffer circuits (1A to 1C) (see timings T11 to T12 and timings T13 to T14 in FIG. 3A).

Examples of the present invention will now be described in detail with reference to the drawings.

### First Example

FIG. 1 is a block diagram of a semiconductor integrated circuit according to a first example. As shown in FIG. 1, a semiconductor integrated circuit 2 is supplied with power from a voltage source 11 via a power source line 3 and ground line 4. The power source line 3 is connected to power source terminals 5, 6 of the semiconductor integrated circuit 2, and the ground line 4 is connected to ground terminals 7, 8 of the semiconductor integrated circuit 2. A power source inductance 9, which is a parasitic element component of the package or printed circuit board, exists in the power source line 3 from the voltage source 11. Similarly, a ground inductance 10 exists in the ground line 4.

An output buffer circuit 1 is provided internally of the semiconductor integrated circuit 2 and is connected to the power source terminal 6 and ground terminal 8. A decoupling capacitor 14 and a switch 15 are connected in series between the power source terminal 5 and ground terminal 7. The switch 15 is constituted by an NMOS transistor and has a gate to which is connected a switch control signal 19, which is the output signal of a switch control circuit 12. A control signal 16 for controlling the on/off operation of the output buffer circuit 1 is connected to the input of the switch control circuit 12. The switch control circuit 12 turns on the switch 15 for a fixed period of time that straddles the switching of the output buffer circuit 1. More specifically, the switch control circuit 12 detects the rising or falling edge of the control signal 16 and outputs the switch control signal 19, which is at the high level for a fixed period of time. The switch control signal 19 is fixed at the low level in a case where there is no change in the logic level of the control signal 16, i.e., in a case where the control signal 16 remains at the high level or low level.

The control signal 16 is connected to the gate of the output buffer circuit 1 via a timing adjustment circuit 13. The timing adjustment circuit 13 delays the control signal 16 to thereby delay the timing at which the output buffer circuit 1 switches. Before the output buffer circuit 1 switches, the switch control circuit 12 turns on the switch 15 to thereby connect the decoupling capacitor 14 to the power source of the semiconductor integrated circuit 2 supplied from the voltage source 11.

Next, the operation of the semiconductor integrated circuit 2 according to the first example will be described with reference to FIG. 2, which is the operation timing chart of the semiconductor integrated circuit 2 in FIG. 1. In FIG. 2, reference numerals 16, 17, 18 and 19 denote the control signal 16 in FIG. 1, a delayed control signal 17 that is the output signal of the timing adjustment circuit 13, an output signal 18 from the output buffer circuit 1 and the switch control signal 19, respectively.

In FIG. 2, the control signal 16 rises from the low to the high level at timing T0. When this occurs, the switch control circuit 12 detects the rising edge of the control signal 16 and applies the high-level switch control signal 19 to the gate of the switch 15. When the high-level switch control signal 19 is applied thereto, the switch 15 turns on and the decoupling capacitor 14 is connected to the power to the semiconductor integrated circuit 2 supplied from the voltage source 11. Upon elapse of a time period D0, which is the result of a delay by the timing adjustment circuit 13, from the moment the control signal 16 rises, the delayed control signal 17, which is the output of the timing adjustment circuit 13, rises from the low to the high level. The output buffer circuit 1 receives the delayed control signal 17 and raises the output signal 18 from the low to the high level following a delay equivalent to a delay time period D2. When the output signal 18 rises from the low to the high level, a large current flows from the power source line 3 to the power source terminal 6. At this time, however, the switch 15 is on and therefore the decoupling capacitor 14 has been connected to the power supplied from the voltage source 11 of semiconductor integrated circuit 2. Accordingly, a current is supplied also to the output buffer circuit 1 from the decoupling capacitor 14 and the effects of voltage fluctuation and power source noise in the power source due to switching of the output buffer circuit 1 are suppressed.

Next, at timing T1, a fixed period of time elapses from the rise of the control signal 16 at timing T0 and therefore the switch control circuit 12 lowers the switch control signal 19 from the high to the low level. At the timing T1, time has elapsed from the moment the voltage of the output buffer circuit 1 changed from the low to the high level. As a result, the large current that flowed when the output buffer circuit 1 changed from the low to the high level has already subsided. When the switch control signal 19 falls at timing T1, the switch 15 is turned off and the decoupling capacitor 14 is disconnected from the power supplied from the voltage source 11 to the semiconductor integrated circuit 2.

Next, at timing T2, the control signal 16 falls from the high to the low level. When this occurs, the switch control circuit 12 detects the falling edge of the control signal 16 and applies the high-level switch control signal 19 to the gate of the switch 15. When the high-level switch control signal 19 is applied thereto, the switch 15 turns on again and the decoupling capacitor 14 is connected to the power to the semiconductor integrated circuit 2 supplied from the voltage source 11. Upon elapse of a time period D1, which is the result of a delay by the timing adjustment circuit 13, from the moment the control signal 16 falls, the delayed control signal 17, which is the output of the timing adjustment circuit 13, falls from the high to the low level. The output buffer circuit 1 receives the delayed control signal 17 and lowers the output signal 18 from the high to the low level following a delay equivalent to a delay time period D3. When the output signal 18 falls from the high to the low level, a large current flows from the output buffer circuit 1 to the ground line 4 via the ground terminal 8. At this time, however, the switch 15 is on and therefore the decoupling capacitor 14 has been connected to the power supplied from the voltage source 11 of semiconductor integrated circuit 2. Accordingly, a current is supplied also to the output buffer circuit 1 from the decoupling capacitor 14 and the effects of voltage fluctuation and power source noise in the power source due to switching of the output buffer circuit 1 are suppressed.

Next, at timing T3, a fixed period of time elapses from the fall of the control signal 16 at timing T2 and therefore the switch control circuit 12 lowers the switch control signal 19 from the high to the low level. At the timing T3, time has elapsed from the moment the control signal 18 of the output buffer circuit 1 changed from the high to the low level. As a result, the large current that flowed when the control signal 18 changed from the high to the low level has already subsided. Accordingly, when the switch control signal 19 falls at timing T3, the switch 15 is turned off and the decoupling capacitor 14 is disconnected from the power supplied from the voltage source 11 to the semiconductor integrated circuit 2.

Thus, upon receiving the control signal 16, the switch control circuit 12 turns on the switch 15 only when the logic of the output buffer circuit 1 inverts and a large switching current flows into the output buffer circuit 1, thereby suppressing power source noise and ground noise produced in the power of the voltage source 11, this noise being power source noise and ground noise ascribable to the switching operation of the output buffer circuit 1. In accordance with the above-described example, a jitter characteristic equivalent to the jitter produced in the conventional circuit can be realized using a capacitor having a capacitance value smaller than that of the conventional circuit. This has the effect of enabling a reduction in the mounted capacitance.

The principle of operation of the present invention will now be described with reference to FIGS. 3A-3C. FIG. 3A illustrates the voltage waveform on the power source line 3 assuming a case where the decoupling capacitor is not provided. From timing T11 to timing T12, the output buffer circuit 1 rises from the low to the high level and a current flows into the output buffer circuit 1 from the power source line 3, whereby the power source voltage of the power source line 3 drops and a high power source noise is produced. Similarly, from timing T13 to timing T14, the output buffer circuit 1 rises from the low to the high level and power source noise is produced. It should be noted that in a case where the output buffer circuit 1 falls from the high to the low level, ground noise is produced in the ground line 4. Further, although the waveform of power source noise is dependent upon the value of the power source inductance 9, it is assumed in FIGS. 3A-3C that the power source inductance is comparatively small.

FIG. 3B illustrates timing at which the decoupling capacitor 14 is connected to the power source by the switch control signal 19. From timing T11 to timing T12 and from timing T13 to timing T14, the switch control signal 19 attains the high level, the switch 15 is turned on and the decoupling capacitor 14 is connected to the power source.

FIG. 3C illustrates the waveform of the power source line 3 that is the result of exercising control by the switch control signal 19 so as to connect and disconnect the decoupling capacitor 14 to and from the power source. From timing T11 to timing T12 and from timing T13 to timing T14, the decoupling capacitor 14 is connected to the power source, whereby power source noise due to the switching of the output buffer circuit 1 can be suppressed and power source noise leveled.

### Second Example

FIG. 4 is a block diagram of a semiconductor integrated circuit according to a second example. The second example differs from the first example of FIG. 1 in that the timing adjustment circuit 13 is removed from the arrangement of FIG. 1. In other aspects of structure and operation, the example is substantially the same as the first example and therefore components in FIG. 4 identical with those shown in FIG. 1 are designated by like reference characters and need not be described again. In the first example, in order to cause the output buffer circuit 1 to switch after the rising or falling edge of the control signal 16 is detected by the switch control circuit 12 and the switch 15 is turned on, the control signal 16 is applied to the output buffer circuit 1 upon being delayed by the timing adjustment circuit 13. However, if the operation of the output buffer circuit 1 is slow and the length of time from the moment the edge of the control signal 16 changes until the moment the switch control circuit 12 turns on the switch 15 is shorter than the length of time it takes for the output buffer circuit 1 to start the switching operation, then there is no need to provide the timing adjustment circuit 13. In this case, effects similar to those of the first example are obtained even without the provision of the timing adjustment circuit 13, as shown in FIG. 4.

### Third Example

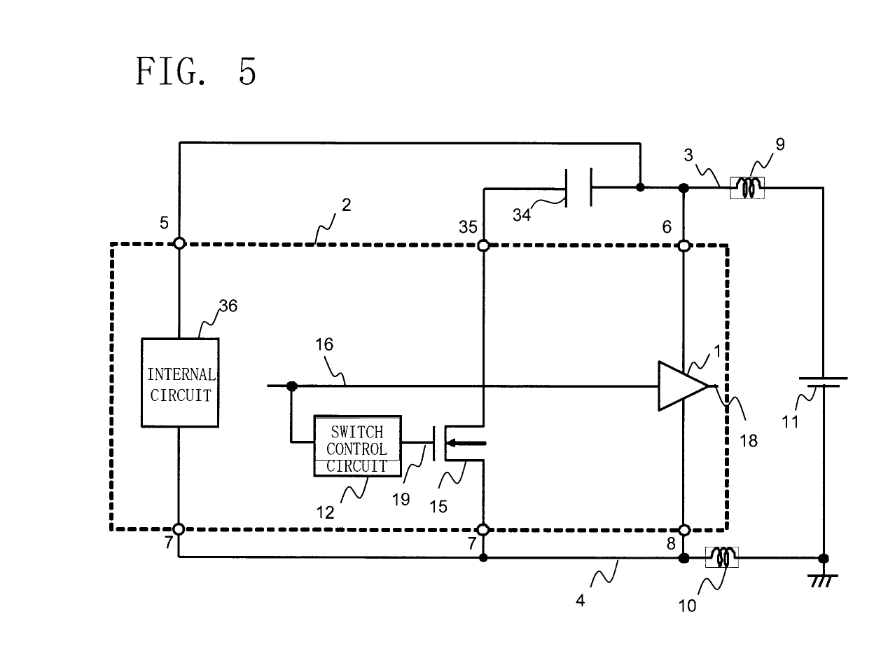

FIG. 5 is a block diagram of a semiconductor integrated circuit according to a third example. In the third example, the decoupling capacitor incorporated within the semiconductor integrated circuit 2 in the first example is provided exterior to the semiconductor integrated circuit 2. Providing a large-capacitance decoupling capacitor within the semiconductor integrated circuit 2 is difficult in terms of manufacture. Therefore, in a case where it is necessary to provide a large-capacitance decoupling capacitor, the decoupling capacitor can also be provided on the exterior of the semiconductor integrated circuit, as shown in FIG. 5. In this case, it is necessary to provide a decoupling capacitor connecting terminal 35 in addition to the power source terminals 5 and 6. An internal circuit 36 is connected between the power source terminal 5 and the ground terminal 7. The ground terminal 7 may be a common ground terminal for both the switch 15 and internal circuit 36, or separate ground terminals 7 may be provided for these, as shown in FIG. 5. In the third example, the timing adjustment circuit 13 has been eliminated in a manner similar to that of the second example.

### Fourth Example

FIG. 6 is a block diagram of a semiconductor integrated circuit according to a fourth example. In FIG. 6, a plurality of output buffer circuit blocks 51A, 51B, 51C are provided. The output buffer circuit blocks 51A, 51B, 51C are respectively provided with output buffer circuits 1A, 1B, 1C; switches 15A, 15B, 15C; decoupling capacitors 14A, 14B, 14C; switch control circuits 12A, 12B, 12C; and timing adjustment circuits 13A, 13B, 13C.

The individual output buffer circuit blocks 51A, 51B, 51C have substantially the same internal structure as that of the semiconductor integrated circuit 2 of the first example. An example of the internal structures of the switch control circuits 12A, 12B, 12C and timing adjustment circuits 13A, 13B, 13C is illustrated in the rectangles indicated by the dashed lines. The switch control circuits 12A, 12B, 12C include respective inverters 41 cascade-connected in four stages the first stages of which receive the control signals 16A to 16C as the input, and exclusive-OR (XOR) gates 42 the inputs to which are the control signals 16A to 16C and the output signal from the final stage of the four-stage cascade-connected inverters 41. High-level outputs are produced at the outputs of the XOR gates 42 following a delay time, which is equivalent to the four inverters, from the rising or falling edges of the control signals 16A to 16C. Using inverters 41 cascade-connected in two stages, the timing measurement circuits 13A, 13B, 13C generate control signals 17A to 17C, respectively, obtained by delaying the control signals 16A to 16C by an amount equivalent to the two inverters. If it is assumed that the switching times of the switches 15A to 15C and output buffer circuits 1A to 1C are zero, the edges of the control signals 16A to 16C are detected and the switches 15A to 15C are turned on to thereby connect the decoupling capacitors 14A to 14C to the power source. As a result, the output buffer circuits 1A to 1C switch following a delay equivalent to the two stages of inverters applied by the timing adjustment circuits 13A to 13C. Furthermore, following a delay equivalent to the four stages of inverters applied by the switch control circuits 12A to 12C from the edges of the control signals 16A to 16C, the switches 15A to 15C turn off so that the decoupling capacitors 14A to 14C are disconnected from the power source.

In FIG. 6, the power source terminal 6 and ground terminal 8 are shared by three output buffer circuits 51A, 51B, 51C. However, the power source terminal 6 and ground terminal 8 may be provided separately for every output buffer circuit block. Further, in FIG. 6, the output signals 18A to 18C of the respective output buffers 1A to 1C are connected to external output terminals 43A to 43C, respectively, whereby the control signals are led out to the outside. Furthermore, in FIG. 6, power source inductance 9 and ground inductance 10 ascribable to the power source wiring and ground wiring exist not only exterior to the semiconductor integrated circuit 2 but also inside the semiconductor integrated circuit 2.

In the fourth example shown in FIG. 6, the decoupling capacitors are provided independently for respective ones of the output buffer circuits, and the timings at which the decoupling capacitors are connected to the power source are also controlled independently for respective ones of the output buffer circuits. Since the timings at which the decoupling capacitors are connected to the power source are thus controlled independently for respective ones of the output buffers, it does not matter whether the timings at which the output buffer circuits switch are simultaneous or different from one another. Since it is unnecessary to take into consideration the timings at which other output buffer circuits are turned on and off, control of the timings for turning the switches on and off is no longer difficult even if the circuitry of the semiconductor integrated circuit is made more complex and larger in scale.

### Fifth Example

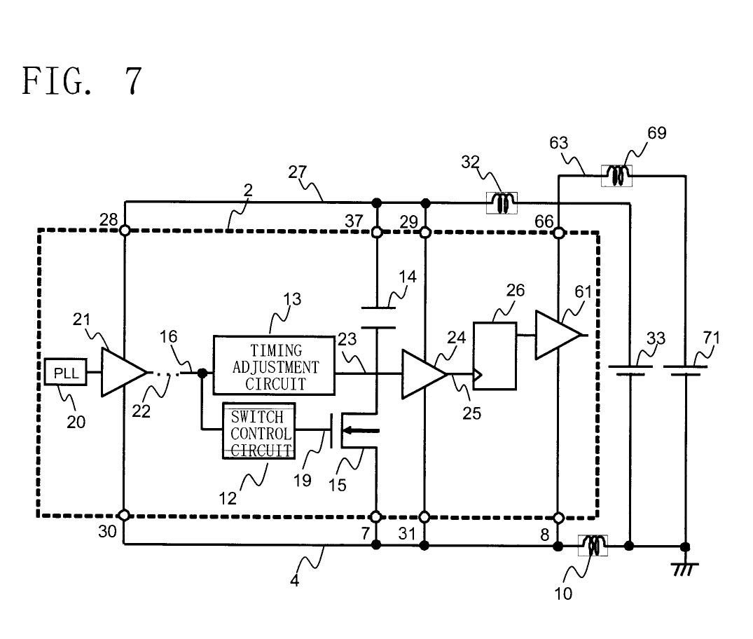

FIG. 7 is a block diagram of a semiconductor integrated circuit according to a fifth example. In all of the first to fourth examples, the output buffer circuit that drives the external output terminal is provided with the decoupling capacitor, the switch for connecting the decoupling capacitor to the power source and the switch control circuit 12. However, a buffer circuit exhibiting high switching noise is not limited to the output buffer that drives the external terminal. The fifth example is one in which the decoupling capacitor is connected to the power source of the final-stage buffer of a clock tree synthesis (referred to simply as “CTS” below) buffer circuit via the switch.

In FIG. 7, power is supplied from a second voltage source 33. This supply of power is separate from that of a power source 71 of an output buffer circuit 61, which is an external output buffer. In FIG. 7, a CTS buffer 21 of an initial stage buffers a clock that has been generated by a PLL 20. A clock signal driven by the CTS buffer 21 of the initial stage is input to a final-stage CTS buffer via the timing adjustment circuit 13. In order to suppress the effects of switching noise of the final-stage CTS buffer, the switch 15, decoupling capacitor 14 and switch control circuit 12 are provided. It should be noted that power for the initial-stage CTS buffer 21 and final-stage CTS buffer is supplied from the second voltage source 33 via power source terminals 28, 29, respectively. Therefore the decoupling capacitor 14 and switch 15 are also connected to the second voltage source 33, which supplies the internal circuitry with power, and not to the power source 71 that supplies power to the output buffer circuit 61, which is the external output buffer. Further, a power source inductance 32, which is a parasitic element component ascribable to the package or printed circuit board, also exists in a second power source line 27 leading from the second voltage source 33 to the power source terminals 28, 29 and 37.

Further, this example is similar to the first to fourth examples in that the switch control circuit 12 detects the edge of the control signal 16 and controls the on/off operation of the switch 15. By virtue of the arrangement described above, not only the effects of switching noise produced by switching of an external output buffer but also the effects of switching noise produced by operation of internal circuit can be reduced, as set forth in the fifth example.

It should be noted that in each of the examples set forth above, the position at which the decoupling capacitor is connected may be in the vicinity of the switching circuit that is the source of noise or may be in the vicinity of a circuit that shares the same power source as that of the switching circuit and is influenced by the power source noise ascribable to this switching circuit.

In the present invention, the following modes are possible.
(Mode 1): as mentioned as the first aspect.
(Mode 2):

The decoupling capacitor may be incorporated within the semiconductor integrated circuit.
(Mode 3):

The switching circuit may be a buffer circuit, and the switch control circuit may detect an edge of an input signal to the buffer circuit and turn on the switch.
(Mode 4):

The semiconductor integrated circuit may further include a timing adjustment circuit that receives the control signal and adjusts timing of switching of the switching circuit and the timing at which the switch is turned on.
(Mode 5): as mentioned as the second aspect.
(Mode 6):

The plurality of decoupling capacitors connected to respective ones of the plurality of switches may be incorporated within the semiconductor integrated circuit.
(Mode 7):

The plurality of switching circuits may be output buffer circuits connected to corresponding external output terminals of the semiconductor integrated circuit; and the plurality of switch control circuits may detect the edges of input signals to the output buffer circuits and turn on the corresponding switches.
(Mode 8):

The semiconductor integrated circuit may further include timing adjustment circuits, which are provided for respective ones of the plurality of switching circuits, that receive the control signals and adjust the timings of switching of the switching circuits and the timings at which the switches are turned on.
(Mode 9): as mentioned as the third aspect.
(Mode 10):

The switching circuit that exhibits a high switching noise may be a plurality of output buffer circuits; a plurality of the coupling capacitors, a plurality of the switches and a plurality of the switch control circuits may be internally provided in the semiconductor integrated circuit in correspondence with respective ones of the plurality of output buffer circuits; and when outputs of the plurality of output buffer circuits are inverted, the respective corresponding switches may be turned on to thereby level the effects of switching noise due to the plurality of output buffer circuits.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor integrated circuit comprising:
a switching circuit;
a switch that changes over whether a decoupling capacitor is connected to a power source of said switching circuit; and
a switch control circuit configured to detect a control signal and turn on said switch for a fixed period of time that straddles switching of said switching circuit, thereby connecting the decoupling capacitor to the power source of said switching circuit, wherein said control signal causes switching of said switching circuit.

2. The semiconductor integrated circuit according to claim 1, wherein the decoupling capacitor is incorporated within the semiconductor integrated circuit.

3. The semiconductor integrated circuit according to claim 1, wherein said switching circuit is a buffer circuit; and
said switch control circuit detects an edge of an input signal to said buffer circuit and turns on said switch.

4. The semiconductor integrated circuit according to claim 1, further comprising a timing adjustment circuit that receives the control signal and adjusts timing of switching of said switching circuit and the timing at which said switch is turned on.

5. A semiconductor integrated circuit comprising:
a plurality of switching circuits;
a plurality of switches provided in correspondence with respective ones of said plurality of switching circuits that change over whether decoupling capacitors are connected to a power source of said corresponding switching circuits; and
a plurality of switch control circuits provided in correspondence with respective ones of said plurality of switching circuits configured to detect control signals and turn on said corresponding switches for a fixed period of time that straddles switching of the corresponding switching circuits, wherein said control signals cause switching of the corresponding switching circuits.

6. The semiconductor integrated circuit according to claim 5, wherein the plurality of decoupling capacitors connected to respective ones of said plurality of switches are incorporated within the semiconductor integrated circuit.

7. The semiconductor integrated circuit according to claim 5, wherein said plurality of switching circuits are output buffer circuits connected to corresponding external output terminals of the semiconductor integrated circuit; and
said plurality of switch control circuits detect the edges of input signals to the output buffer circuits and turn on said corresponding switches.

8. The semiconductor integrated circuit according to claim 5, further comprising timing adjustment circuits, which are provided for respective ones of said plurality of switching circuits, that receive the control signals and adjust the timings of switching of said switching circuits and the timings at which said switches are turned on.

9. A method of leveling switching noise in a semiconductor integrated circuit having a plurality of switching circuits, comprising:
providing the semiconductor integrated circuit with a switch, which changes over whether a decoupling capacitor is connected to a power source of the switching circuits, and a switch control circuit, which controls on/off operation of the switch, in correspondence with a switching circuit that exhibits a high switching noise among the plurality of switching circuits; and
turning on the switch for a fixed period of time that straddles switching of said switching circuit to thereby connect the decoupling capacitor to the power source and suppress switching noise due to said switching circuit.

10. The method according to claim 9, wherein the switching circuit that exhibits a high switching noise is a plurality of output buffer circuits;
a plurality of the coupling capacitors, a plurality of the switches and a plurality of the switch control circuits are internally provided in the semiconductor integrated circuit in correspondence with respective ones of the plurality of output buffer circuits; and
when outputs of the plurality of output buffer circuits are inverted, the respective corresponding switches are turned on to thereby level the effects of switching noise due to the plurality of output buffer circuits.
